(19) United States
(12) Patent Application Publication
(10) Pub. No.: US 2015/0147621 A1
(43) Pub. Date: May 28, 2015

(54) METHODS FOR THE FORMATION OF BETA ALUMINA ELECTROLYTES, AND RELATED STRUCTURES AND DEVICES

(71) Applicant: General Electric Company, Schenectady, NY (US)

(72) Inventors: Todd Michael Striker, Ballston Lake, NY (US); Richard Louis Hart, Broadalbin, NY (US); Matthew Joseph Alinger, Delmar, NY (US); Leonardo Ajdelsztajn, Niskayuna, NY (US)

(73) Assignee: General Electric Company, Schenectady, NY (US)

(21) Appl. No.: 14/090,738

(22) Filed: Nov. 26, 2013

(51) Int. Cl. H01M 2/14; C23C 4/12; C23C 4/06; C23C 4/10; C23C 14/34; H01M 6/36

(52) U.S. Cl. CPC H01M 2/145; C23C 14/34; H01M 6/36; C23C 4/06; C23C 4/105; C23C 4/127; C23C 4/128; C23C 4/125
USPC 429/112; 204/192.15; 427/446; 427/453

(57) ABSTRACT

A method for preparing an electrolyte separator for an electrochemical device is described. The method includes the step of applying a beta″-alumina coating composition, or a precursor thereof, to a porous substrate, by an atmospheric, thermal spray technique. An electrochemical device is also described. Some of these devices include an anode, a cathode, and an electrolyte separator disposed between the anode and the cathode. The separator includes a thermally-sprayed layer of beta″-alumina, disposed on a porous substrate. The electrochemical device can be used as an energy storage system, or for other types of end uses.

### TECHNICAL FIELD

This invention generally relates to electrolyte structures for electrochemical cells, and methods for their preparation. In some particular embodiments, it relates to energy storage devices, such as batteries.

### BACKGROUND OF THE INVENTION

Metal chloride batteries, especially sodium-metal chloride batteries with a molten sodium negative electrode (usually referred to as the anode) and a beta-alumina solid electrolyte, are of considerable interest for energy storage applications. In addition to the anode, the batteries include a positive electrode (usually referred to as the cathode) that supplies/receives electrons during the charge/discharge of the battery. The solid electrolyte is usually an ion conductor, and functions as the membrane or “separator” between the anode and the cathode.

When these metal chloride batteries are employed in mobile applications like hybrid locomotives or plug-in electric vehicles (PHEV), the batteries are often capable of providing power surges (high currents) during the discharge cycle. In an ideal situation, the battery power can be achieved without a significant loss in the working capacity and the cycle life of the battery. The advantageous features of these types of batteries provide opportunities for applications in a number of other areas as well. Examples include their incorporation into uninterruptable power supply (UPS) devices; or as part of a battery backup system for a telecommunications (“telecom”) device, sometimes referred to as a telecommunication battery backup system (TBS).

One typical, general design for metal chloride cells and other types of thermal batteries is depicted in FIG. 5, which will be explained in some detail, in the detailed description. The separator tube, disposed in the cell case, generally defines an anodic chamber and a cathodic chamber. The anodic chamber is usually filled with an anodic material like sodium. The cathodic chamber contains a cathode material such as nickel and sodium chloride, and a molten electrolyte, usually sodium chloroaluminate (NaAlCl₄).

The separator structure is a critical component for thermal batteries such as the sodium metal chloride cells. While various materials can be used to make the separator (e.g., in the form of a tube), highly specialized alumina materials are preferred, such as beta″-alumina (beta double prime alumina or “beta prime prime alumina”). The term “beta alumina” will sometimes be used herein to refer to this material, unless otherwise indicated. Beta alumina is known in the art as a unique, isomorphic form of aluminum oxide, characterized by a layered, rhombohedral crystal structure. The material can be used to rapidly transport sodium and other selected ions during electrochemical reactions.

There are various challenges associated with preparing beta alumina separator structures, which are required to have a number of select properties. In addition to the high level of ion conductivity, separator structures such as tubes must be capable of preventing electronic conductivity; while also exhibiting very low resistivity, i.e., ionic resistivity. Separator tubes, in particular, must possess relatively high strength; and must be capable of formation into thin-walled structures. The separator structures also must retain mechanical integrity and a specified level of electrochemical performance over many years.

One standard method for preparing beta alumina materials includes the step of preparing a uniform mixture of powdered basic oxides like Na₂O and alpha-Al₂O₃, along with stabilizing compounds like lithium oxide or magnesium oxide. The mixture is then calcined to effect the reaction that will induce the crystalline transformation to beta-alumina. In some cases, the material is then milled and spray-dried to obtain a desired particle-form, which can be granulated. The granulated material is then usually pressed and consolidated into a desired shape, e.g., the tube shapes in some types of metal chloride cells. The shaped material is then sintered at high firing temperatures, to obtain the desired beta alumina structure.

While these conventional ceramic processing techniques are suitable in some circumstances, there are drawbacks as well. The processing steps can be lengthy, and consume significant amounts of energy, e.g., for high-temperature treatments of long duration. Moreover, in some cases, it is very desirable that the beta alumina structure be very thin, so as to lower resistivity, and increase efficiency and power output. The conventional processing techniques cannot usually be used to form the thin membrane structures. Other techniques might be useful for this objective, such as various tape-casting techniques. However, tape casting also requires multiple processing steps, and high-temperature treatments.

Beta″-alumina films have also been applied by thermal plasma deposition, as described by Kim et al, in “Fabrication of β”-alumina films as a thermoelectric material by thermal plasma processing,” Surface and Interface Analysis 35 (2003), pages 658-661. However, the conditions and powder materials used in that reference do not appear to have resulted in a coating of beta″-alumina phase purity. Moreover, the presence of undesirable precursor materials and low conductivity beta-alumina in the coating was significant. In addition, the granular structure of the coating did not adequately demonstrate feasibility to hermetic and dense coatings. The Kim reference also does not satisfactorily teach how a thermal plasma beta″-alumina coating would be deposited onto a structure of reasonable porosity, and inherently seal the porous structure, such that an electrochemical device would be functional.

With these considerations in mind, new techniques for preparing electrolyte structures such as separators would be welcome in the art. The methods should be more efficient than traditional processing systems, e.g., in reducing the number of processing steps. The methods would also advantageously be carried out at room temperatures, or at least avoid the necessity for multiple, high-temperature treatments. Moreover, it would be desirable if the methods could be used to form very thin separator membrane structures, e.g., as thin as about 25 microns. Furthermore, the new techniques should not adversely affect the performance of devices which include the separator structures (such as batteries), in any significant way.

### BRIEF DESCRIPTION

One embodiment of the invention is directed to a method for preparing an electrolyte separator for an electrochemical device, comprising the step of applying a beta″-alumina (beta double prime alumina) coating composition, or a precursor thereof, to a porous substrate, by an atmospheric, thermal spray technique.

Another embodiment of the invention relates to an electrochemical device. The device comprises an anode, a cathode, and an electrolyte separator disposed between the anode and the cathode, and configured to seal and separate the anode from the cathode. The separator comprises a thermally-sprayed layer of beta″-alumina (beta double prime alumina) disposed on a porous substrate. The electrochemical device can be used as an energy storage product.

### BRIEF DESCRIPTION OF DRAWINGS

FIG. 1 is a simplified schematic of a suspension spray system related to embodiments of the invention.

FIG. 2 is a simplified depiction of a porous substrate on which a coating material is deposited by a thermal spray technique.

FIG. 3 is a perspective, cross-sectional view of a planar battery, according to embodiments of this invention.

FIG. 4 is a perspective, cross-sectional view of another planar battery, according to embodiments of this invention.

FIG. 5 is a perspective, cross-sectional view of a tubular battery, according to embodiments of this invention.

FIG. 6 is a scanning electron microscopy (SEM) image of a thermal spray-deposited coating of a beta alumina material on a substrate.

FIG. 7 is another scanning electron microscopy (SEM) image of a thermal spray-deposited coating of a beta alumina material on a substrate.

FIG. 8 is a graph of several X-ray diffraction (XRD) patterns for coatings deposited according to embodiments of the present invention.

FIG. 9 is a graph depicting conductivity as a function of temperature, for a coating of a beta alumina material, deposited by a suspension spray technique.

### DETAILED DESCRIPTION

When introducing elements of various embodiments of the present invention, the articles “a,” “an,” “the,” and “said” are intended to mean that there are one or more of the elements, unless otherwise indicated. Moreover, the terms “comprising,” “including,” and “having” are intended to be inclusive, and mean that there may be additional elements other than the listed elements. As used herein, the term “and/or” includes any and all combinations of one or more of the associated listed items. Furthermore, unless otherwise indicated herein, the terms “disposed on”, “deposited on” or “disposed between” refer to both direct contact between layers, objects, and the like, or indirect contact, e.g., having intervening layers therebetween.

Approximating language, as used herein throughout the specification and claims, may be applied to modify any quantitative representation that could permissibly vary without resulting in a change in the basic function to which it may be related. Accordingly, a value modified by a term such as “about” is not limited to the precise value specified. In some instances, the approximating language may correspond to the precision of an instrument for measuring the value.

As mentioned previously, embodiments of this invention include the step of applying a beta alumina material to a porous substrate. A wide variety of substrates can be employed, and they are usually formed of a metal or ceramic material. Non-limiting examples of the ceramic material include alumina e.g., beta″ (double prime) alumina or other types of alumina, zirconia, nickel oxide, rutile titanium dioxide (TiO₂), or combinations thereof. Non-limiting examples of suitable metal materials include nickel, chromium, molybdenum, iron, steel such as stainless steel; and various alloys thereof.

The porous substrate can take a number of forms. Very often, it is in the form of a mesh, or screen, e.g., those woven mechanically in the case of metal materials, or extruded or otherwise formed in the case of ceramics. The porosity of the mesh may vary according to a number of factors, such as the specific composition and physical form of beta alumina (or its precursors) being applied to the substrate; as well as the type of thermal spray technique being employed. In some embodiments, the porosity of the structure will be in the range of about 5% to about 70%, with larger values within that range often being preferred. In some specific embodiments related to sodium/nickel chloride batteries, the range will be about 40% to about 60%.

In some preferred embodiments in which the electrolyte separator will be used in a sodium/nickel chloride battery, the pore size will be in the range of about 1 to about 30 microns. The upper limit is influenced considerably by the need to minimize coating defects in a thermal spray deposition, while the lower limit is influenced by mass transport characteristics for the flow of molten sodium during operation of the battery. In some specific embodiments, the pore size range will be about 10 microns to about 20 microns.

As also mentioned previously, a beta alumina composition is applied to the substrate. Beta alumina materials (i.e., the beta double prime alumina) are commercially available; and their preparation is known in the art. Useful information can be found, for example, in the Journal of Materials Science: Materials in Electronics, “Preparation of Beta-Alumina Powder from Kaolin-Derived Aluminium Sulphate Solution”, December 1996, V. 7, Issue 6, pp. 385-389; and in EP Patent 1213781 A2; both of which are incorporated herein by reference. As alluded to previously, these materials can also be prepared in-house, e.g., from precursor powders, but a number of time-consuming steps are involved in the process.

For the spray processes described below, a number of precursors can also be used. The concept of forming beta alumina materials from precursors is generally known in the art. Examples of instructive references are U.S. Pat. No. 4,151,235; and “The Synthesis of Beta Alumina from Aluminium Hydroxide and Oxyhydroxide Precursors”, Materials Research Bulletin, V. 28, Issue 2, February 1993 145-157. Both of these sources are incorporated herein by reference. Non-limiting examples of precursor materials are aluminum halide compounds, aluminum halide-hydrate compounds, boehmite, sodium carbonate, sodium oxide, sodium aluminate, sodium hydroxide, magnesium aluminate, lithium oxide, lithium hydroxide monohydrate, alpha alumina, and combinations thereof.

As mentioned previously, a thermal spray technique is used to apply the beta alumina (or precursors) to the substrate. As used herein, a “thermal spray technique” is a coating process in which melted or heated materials are sprayed onto a surface. The feedstock, i.e., a coating precursor, is heated by an electrical technique or by chemical means. The electrical technique can be plasma- or arc-based, for example. The chemical technique usually employs some sort of combustion flame. The coating materials are usually fed into the spraying mechanism in powder form. They are heated to a molten or semi-molten state, and accelerated toward the substrate in the form of particles, e.g., micrometer-sized particles. In some preferred embodiments, the thermal spray technique is carried out at atmospheric pressure (e.g., under ambient conditions), or very close to atmospheric pressure, e.g., about 0.8 atm to about 1.2 atm at sea level. Moreover, the technique is carried out at a temperature that is sufficient to melt the coating composition or its precursors, during application of the material(s) to the surface of the substrate.

Usually, the thermal spray technique is a high-velocity fuel technique or a plasma spray technique. Plasma spray techniques are well-known in the art. Examples include vacuum plasma spray deposition (VPS), radio frequency plasma, plasma transfer arc, and air plasma spray (APS). APS techniques are sometimes particularly well-suited for these end use applications, although VPS can provide a number of advantages as well. Many references provide information regarding these techniques, such as U.S. Pat. No. 7,166,373 (Spitsberg et al), and additional documents cited therein.

The high-velocity fuel techniques are also known in the art. They are described in a variety of references, such as the Spitsberg patent listed previously, and “The Science and Engineering of Thermal Spray Coatings”, by Lech Pawlowski. Examples include high velocity oxy-fuel (HVOF), high velocity air fuel (HVAF), and high velocity liquid fuel (HVLF). When the spray technique involves relatively high temperatures, as in the case of some of the HVOF processes, it may be desirable to reinforce the substrate, e.g., with some sort of backing layer or plate.

General HVOF processes are preferred in some embodiments. HVOF is a continuous combustion process in which the powder is injected into the jet stream of a spray gun at very high speeds. Those of ordinary skill in the art are familiar with various HVOF details, such as the selection of primary gases, secondary gasses (if used), cooling gases; gas flow rates; power levels; coating particle size, and the like. In the present instance, the HVOF process allows for in-flight softening or melting of the coating particles that travel from the exit site of the spray gun nozzle to the substrate. The deposited coating particles merge into intimate and informal contact with the substrate and previously-deposited particles, forming a hermetic layer very suitable for electrochemical cells, as described below. It is thought that the higher momentum exhibited by the coating particles results in a denser coating that also is characterized by greater phase purity.

In some preferred embodiments, suspension spray techniques are used, e.g., suspension HVOF. For these techniques, the coating feedstock is dispersed in a liquid suspension before being injected into the jet stream of the spray gun. Distilled or deionized water, alcohols such as ethanol, or water-alcohol mixtures are usually used as the solvent. There are considerable advantages to using a suspension technique. As an example, these techniques permit much easier handling and feeding of very small feedstock particles, e.g., particles having an average size in the range of about 100 nanometers to about 10 microns. Smaller sizes within that range are sometimes preferred, in view of the desire for phase purity. In some specific embodiments, the range would be about 500 nm to about 1500 nm. The suspension medium can vary, but it is often distilled or deionized water, alcohols, or water-alcohol mixtures. (Other organic materials can sometimes be used as well, e.g., propylene).

The particular choice of liquid solvent can be advantageously used to influence combustion temperatures within the spray system. Many aspects of suspension spray techniques are described in “Engineering a New Class of Thermal Spray Nano-Based Microstructures from Agglomerated Nanostructured Particles, Suspensions and Solutions: An Invited Review”, by P. Fauchais et al, Journal of Physics D: Applied Physics 44, 9 (2011) 93001 (version 1-7 Oct. 2011); and in “Suspension HVOF Spraying of Reduced Temperature Solid Oxide Fuel Cell Electrolytes”, J. Berghaus et al, JTII5 17:700-707; Journal of Thermal Spray Technology, 70-Volume 17(5-6) Mid-December 2008. Both of these references are incorporated herein by reference.

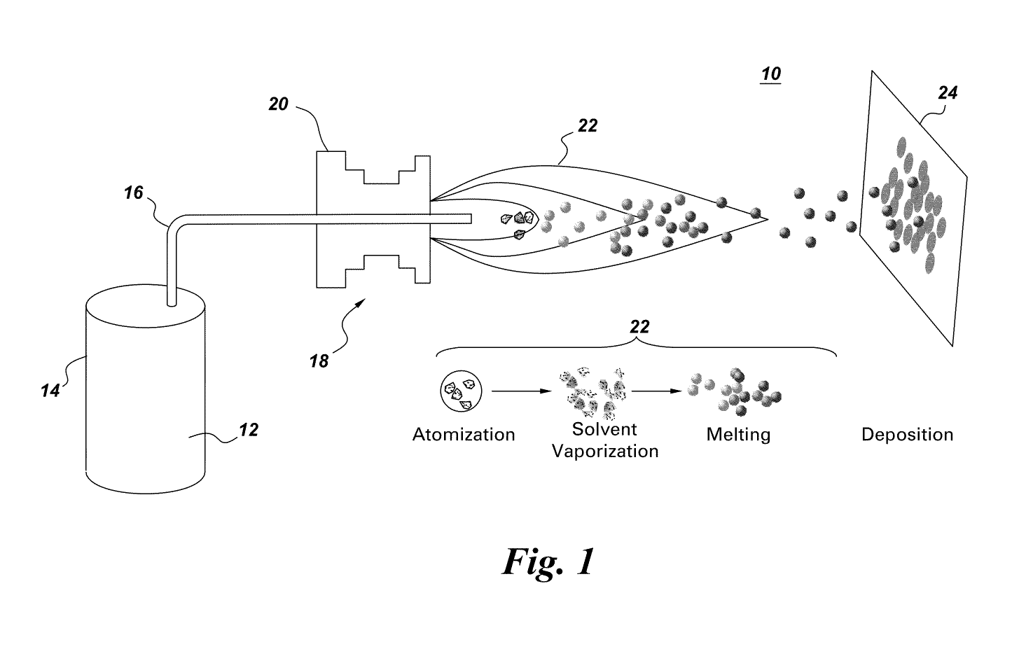

FIG. 1 is a simplified depiction of a suspension spray system 10 suitable for embodiments of the present invention. The feedstock material, e.g., some form of beta″-prime alumina, or its precursors, is dispersed in a solvent to form liquid suspension 12, contained in any suitable chamber 14. The liquid suspension is usually pumped through a conduit 16 to a spray gun 18, which includes a combustion chamber (not specifically shown), and a nozzle 20. Very often, and as depicted here, the nozzle is of the converging-diverging type, which is capable of ejecting the coating material at very high speeds.

The liquid component of the suspension evaporates in the combustor section of the spray gun 18, and the feedstock material is melted as it is injected into the combustion flame 22. At this stage, the coating droplets 23 can undergo various chemical and physical changes, e.g., formation into the beta″-alumina material, as they are propelled toward substrate 24. The velocity of the coating particles in their path to the substrate depends on various factors, but can often range from about 300 m/s to about 700 m/s.

In addition to some of the material and process conditions mentioned above, those skilled in the art are familiar with other parameters: particle size, solvent selection, suspension solid content and feed rate; injector geometry, liquid (fuel) flow rates, carrier gas flow, spray gun traverse speed, nozzle geometry, nozzle-to-substrate distance; and substrate temperature. For example, in some preferred embodiments, the solids content (beta alumina or its precursors) within the liquid suspension will range from about 5% to about 40%, and in some specific applications, from about 10% to about 20%.

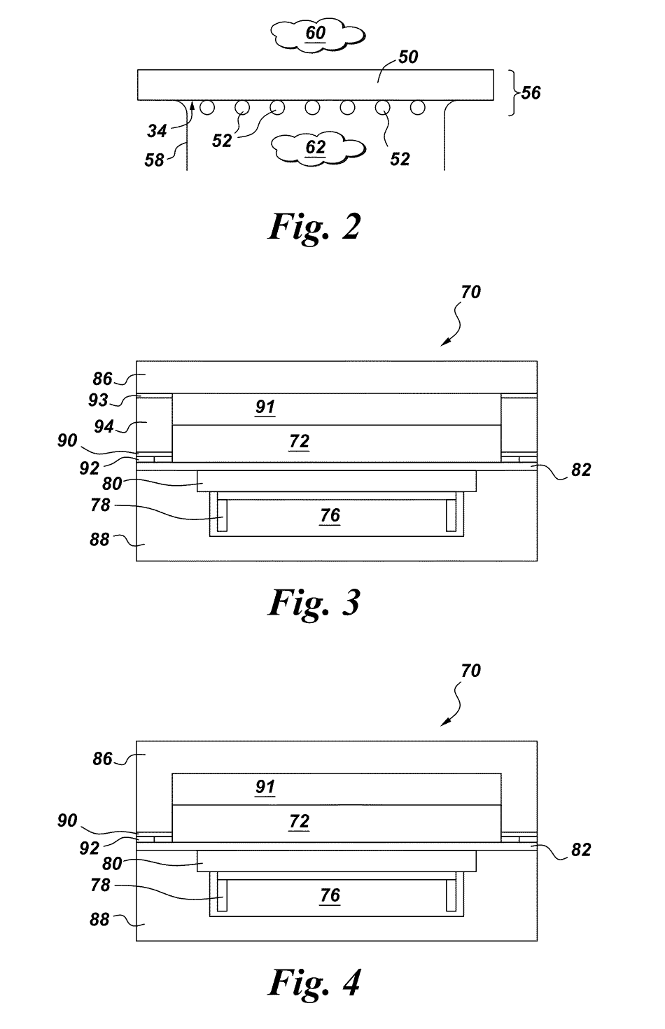

FIG. 2 is a simplified depiction of a porous substrate 50, as described previously. Particles 52 of the beta alumina coating (in beta alumina form, or formed in situ) are applied on a first surface 54 of the substrate, by one of the thermal spray techniques described herein. The cured coating that is formed on the substrate is very thin, e.g., having a thickness in the range of about 10 microns to about 250 microns. (The cured coating is sometimes referred to as a “calcined” coating, e.g., in those instances in which the coating is formed directly from precursor materials).

The substrate and applied beta alumina coating can be used as a membrane 56 that becomes a key component of an electrochemical device, as described below. For example, the membrane structure, held within a suitable frame 58, could separate one electrode region 60, e.g., a cathode, from another electrode region 62, e.g., an anode. The membrane functions as a hermetic layer that would prevent the movement of liquid or gaseous material from one side to the other. (Those skilled in the art understand that the location of the cathode and the anode could be reversed, depending on cell design).

In the case of a sodium-metal halide battery, the membrane still permits the selective transport of sodium ions. Moreover, as alluded to previously, the membrane is much thinner than membrane-separator structures formed by traditional techniques such as the calcining/pressing/firing processes. The reduced thickness allows for rapid ion movement through the cell, which in turn results in very low electrical resistance, and high electrical conductivity through current collectors within the cell.

The process described herein can be used to form electrolytes that are suitable for use in a variety of electrochemical devices. Examples include various types of batteries, e.g., the sodium metal halide types described herein, or sodium sulfur batteries. Electric converters that employ similar types of electrolytes are also within the scope of this invention. One illustrative device is the alkali metal thermal-to-electric converter (AMTEC).

FIG. 3 depicts one exemplary type of planar battery 70, that can take the form of a stack of sodium-nickel chloride cells. The cell includes a cathode 72, often formed of a porous nickel/sodium chloride-impregnated network, with a liquid electrolyte like molten sodium aluminum tetrachloride (NaAlCl₄). The cathode is disposed over a porous substrate 80, usually formed of nickel or a nickel alloy, as described previously. An electrolyte membrane 82, formed of the beta alumina material, forms an inherent seal over the substrate 80, when applied according to the specific thermal spray techniques described herein. The electrolyte separates the anode and the cathode, as those skilled in the art understand, and permits the transport of sodium ions. The relatively thin separator structure 80, preferably in the range of about 10-250 microns, (and not necessarily drawn to scale here, for ease-of-viewing) can provide decreased electrical resistance during operation of the cell, with the attendant benefits noted previously.

In functioning as a seal, membrane 82 extends completely over the upper surface of the anode end plate 88, thereby functioning in part to completely separate the anode from the cathode. With continued reference to FIG. 3, the cell further includes anode 76, which typically contains, or will contain during cell operation, an anodic material like sodium. The anode compartment is sometimes surrounded by a shim 78, which is typically formed of a metal, and which can provide structural support within the cell structure, along with other functions, e.g., thermal or electrical conductivity, and/or space-filling. Other materials, or combinations of materials, can be used in place of the shim, e.g., glass beads, frit, foam, fibers, or a wicking structure for the anode material. It should be noted, however, that other cell designs may not require a shim or filler material.

The planar battery 70 may include various other features, such as cathode end plate 86. Moreover, a ring 90, e.g., formed of alumina (e.g., alpha alumina) or another ceramic material, can be used as an insulator. Although shown as being disposed on the cathode plate, it could also be disposed on the anode plate 88, or on top of the electrolyte 82. In some preferred embodiments, care should be taken, to ensure that the insulator extends far enough in the width-direction. In this manner, the dimension of the alpha alumina layer and beta alumina manner can be matched.

Moreover, a spacer 94, usually formed of metal, could be positioned between the cathode end plate 86 and ring 90. Cavity 91, when present, may contain various types of conductive filler materials, e.g., “springy” or multi-fingered materials that increase electrical conductivity between end plate 86 and cathode 72. In some optional embodiments, a seal 92 could be placed between ring 90 and beta alumina electrolyte layer 82. The seal could be formed from a glass material, or from thermocompression bonding (TCB) materials like nickel or copper. For the design of FIG. 3, the beta alumina electrolyte layer would usually have to extend out, width-wise, so that it lies underneath all of the seal. Alternatively, the seal 92 could be situated directly on top of the upper region of anode end plate 88.

A number of techniques could be used to join end plate 86 to the underlying structure, e.g., contacting the upper surface of metallic spacer 94. Welding techniques, such as tungsten inert gas (TIG), metal inert gas welding (MIG), and laser beam welding, are often very suitable; diffusion bonding could be used as well. Moreover, it should be noted that a number of planar battery cells 70 could be connected together, e.g., by stacking, using one of various conventional series connections. Those skilled in the art may be able to contemplate other features for a planar cell of this type. Additional, general details of interest may be found, for example, in “High Power Planar Sodium-Nickel Chloride Battery”, X. Lu et al, ECS Trans. 2010, Vol. 28, pp. 7-13, which is incorporated herein by reference.

Another type of planar cell is depicted in FIG. 4, and relies in part on the use of compression seals. Features in this figure that are identical to those in FIG. 3 are provided with the same element numerals. As in the embodiment of FIG. 3, the beta alumina electrolyte layer 82 is deposited on the porous metallic substrate 80, according to the techniques described herein.

In this instance (FIG. 4), a spacer is usually not necessary between the cathode end plate and the cathode itself. Compression seal or “sealing gland” 92 is situated between ring 90 and beta alumina electrolyte 82. Seal 92 is designed to completely fill any open region between the cathode and the electrolyte layer, once it has been compressed mechanically during the full assembly of cell 70. In this embodiment, compression seal 92 should usually be formed of a material that is electrochemically inert, and exhibits low reactivity. The material should also be capable of withstanding electrical voltages that exceed the charge potential of the cathode in the cell. As in the case of the embodiment of FIG. 3, number of planar battery cells could be connected together in a stacking arrangement, for example.

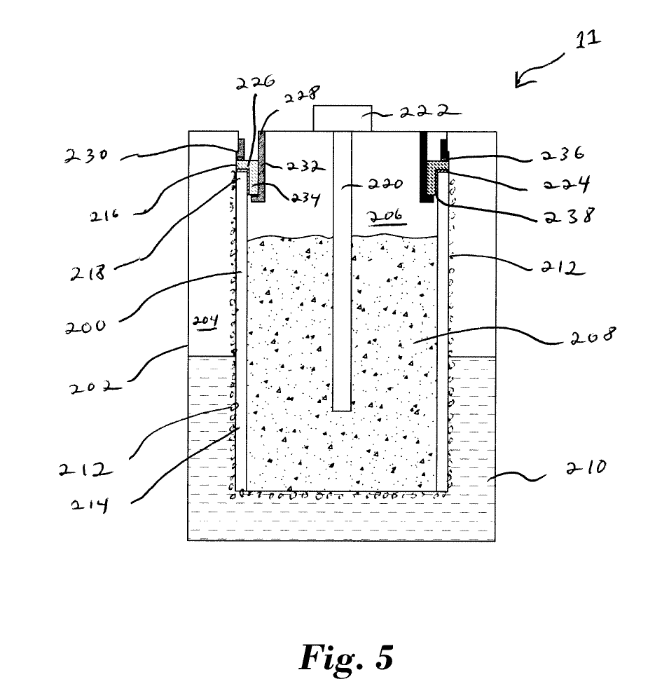

FIG. 5 is a schematic diagram that depicts another type of battery 11, in cylindrical (tubular) form, that can be formed in part according to the techniques described herein. A sodium-metal halide battery cell 11 has an ion-conductive (electrolyte) separator tube 200 (discussed below) disposed in a cell case 202. The tube 200 defines a cathodic chamber 204 between the cell case 202 and the tube, and an anodic chamber 206, inside the tube. Depending on the charge-state of the battery, the anodic chamber 206 is filled with an anodic material 208, e.g. sodium. The cathodic chamber 204 usually contains a cathode material 210 (e.g. nickel and sodium chloride), and a molten electrolyte, usually sodium chloroaluminate (NaAlCl₄).

The separator tube 200 comprises the general membrane structure noted above in FIG. 2, i.e., a beta alumina (beta″-alumina) composition 212 applied on a porous substrate 214. The separator effectively partitions the anode from the cathode, as those skilled in the art understand, and permits the transport of sodium ions therethrough. The relatively thin separator structure (preferably in the range of about 10-250 microns) can provide decreased electrical resistance during operation of the cell, with the attendant benefits noted previously. Moreover, those skilled in the art understand that the relative position of the cathodic chamber and the anodic chamber can be reversed, i.e., with the anodic chamber situated between the separator tube and the cell case; and the cathodic chamber being situated within the tube. (It should also be noted that a battery most often is based on a plurality of interconnected energy storage devices, like those described herein). Related references describing these devices are as follows: 2009/0291365; 2012/0308895; 2013/0224561; 2013/0309544; and 2013/0004828, all of which are incorporated herein by reference.

In the embodiment of FIG. 5, an electrically insulating ceramic collar 216, which may be made of alpha-alumina, is situated at a top end 218 of the tube 200. An anode current collector assembly 220 is disposed in the anode chamber 206, with a cap structure 222, in the top region of the cell. The ceramic collar 216 is fitted onto the top end 218 of the separator tube 200, and is sealed by a glass seal 224. In one embodiment, the collar 216 includes an upper portion 226, and a lower inner portion 234 that abuts against an inner wall of the tube 200.

For the embodiments that generally correspond to FIG. 5, a metal ring 228 or similar structure is often employed to seal the cell 10 at the top end (i.e., its upper region), and to protect the alumina collar 216 in the corrosive environment of this type of cell. Metal ring 228 covers the alpha alumina collar 216, and joins the collar with the current collector assembly 220, underneath the cap structure 222. The metal ring 228 often has two portions; an outer metal ring 230 and an inner metal ring 232, which are joined, respectively, with the upper portion 226 and the lower portion 234 of the ceramic collar 216. In some embodiments, the joining is achieved by the use of active braze seals 236 and 238. The active braze seal 236, the seal 238, or both, may be formed by using one of a variety of suitable braze alloy compositions. The collar 216 and the metal ring 228 may be temporarily held together with an assembly (e.g., a clamp), or by other techniques, until sealing is complete. (This seal construction is also generally described in pending U.S. patent application Ser. No. 13/538,203, filed on Jun. 29, 2012, for R. Adharapurapu et al, and incorporated herein by reference). Those skilled in the art understand that other sealing techniques could also be used, e.g., welding or thermal compression bonding (TCB).

However, for other embodiments of this invention, at least some of the sealing structure can be obtained by way of the spray process used to apply the beta alumina coating. For example, with reference to FIG. 5, it may be possible to deposit a seal that is similar to glass seal 224, using the thermal spray technique, so that collar 216 still becomes attached to the upper end of tube 200. In general, a thermally-sprayed layer of beta″-alumina can be used in any location requiring a seal to prevent the flow of electrode and/or electrolyte material out of any compartment within an electrochemical device.

### EXAMPLES

The examples that follow are merely illustrative, and should not be construed to be any sort of limitation on the scope of the claimed invention. Unless specified otherwise, all ingredients may be commercially available from such common chemical suppliers as Alpha Aesar, Inc. (Ward Hill, Mass.), Sigma Aldrich (St. Louis, Mo.), Spectrum Chemical Mfg. Corp. (Gardena, Calif.), and the like.

### Example 1

Fine particle beta alumina powder was milled to approximately 1 um in size, and suspended in ethanol to form a slurry. (It was also determined that water could be used as the medium). The slurry was then injected in a DJ 2600 HVOF (high velocity oxi-fuel) spray system, using pressure pots and appropriate modifications to the gun, so that it could accept liquid feedstock instead of dry powder. The gun used either an air-cooled or a water cooled nozzle configuration, and the spray parameters and sample preparation are specified below:

TABLE 1

| Target | | | | | | | |
|---|---|---|---|---|---|---|---|
| Coating | | | | | Gun | | Spray |
| Thickness^{(a)} | Usage | H₂ | O₂ | Air | Speed^{(b)} | Step | Distance |
| Micron (s) | lb | SLPM | SLPM | SLPM | mm/s | mm | in |
| 50 | 0.3 | 66 | 35 | 32 | 1000 | 4 | 3 |
| | | | | | | | 4 |
| | | | | | | | 5 |
| | | | | | | | 6 |

Notes:
^{(a)}Powder was Beta″ Alumina SD68, used in an ethanol-based slurry.
^{(b)}The coating spray angle was 90 degrees; and 20 coating passes were used.

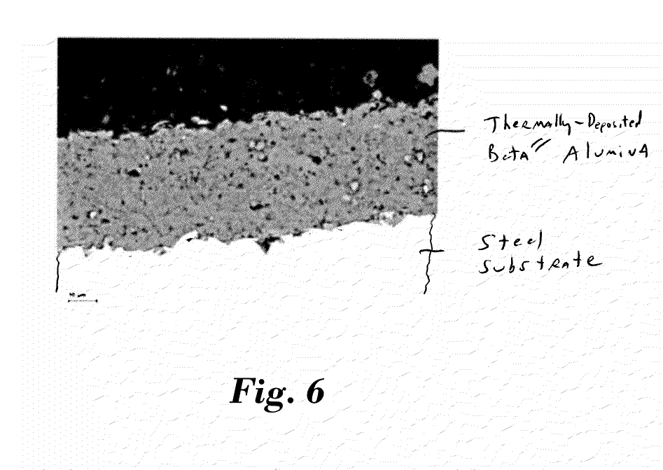

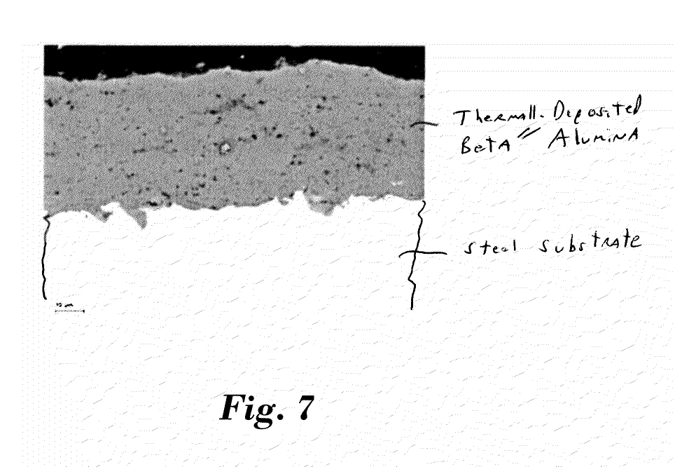

FIG. 6 is a scanning electron microscopy (SEM) image of an HVOF-deposited coating of beta alumina on an E-Brite substrate, using a water-cooled nozzle at a 3 inch (7.6 cm) spray distance. The coating that was examined was about 11% porous, with an average pore size less than 5 microns.

FIG. 7 is an SEM image of an HVOF thermal spray coating deposited, using an air-cooled nozzle, and a 3 inch (7.6 cm) spray distance A dense 50 micron layer was demonstrated, with 5% porosity.

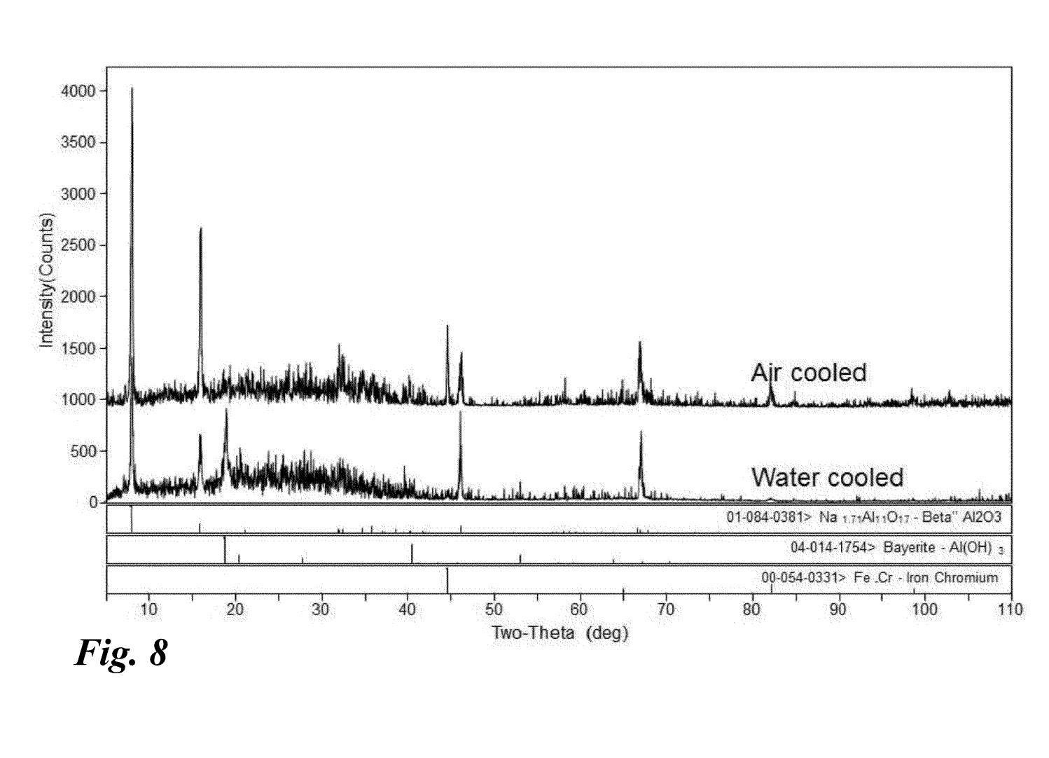

FIG. 8 shows the XRD patterns for coatings deposited, using water- and air-cooled nozzles. In each instance, the majority phase was beta″ alumina. A small amount of bayerite was observed in interlamellar regions for the coating associated with the water cooled nozzle.

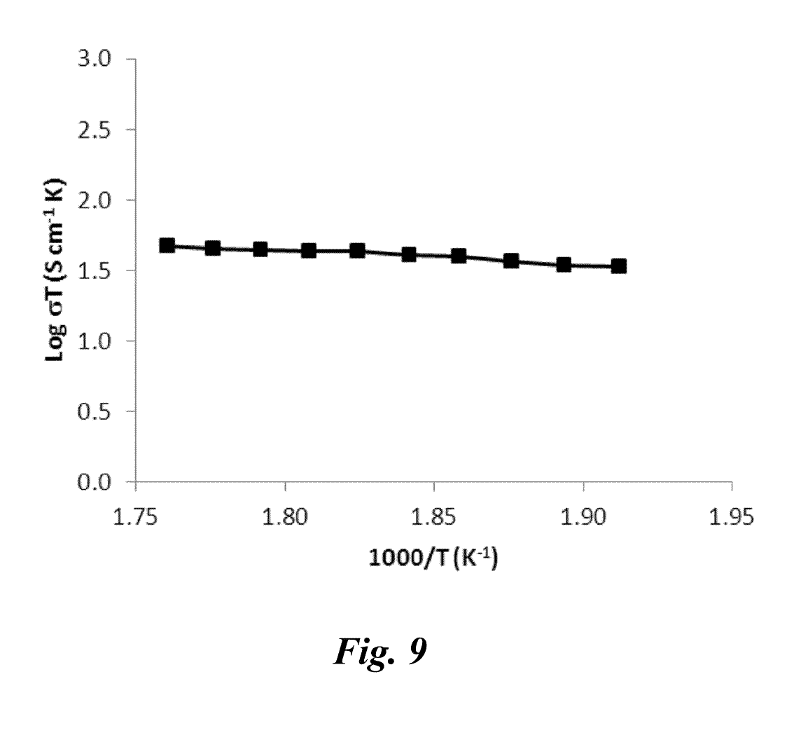

The electrical sheet conductivity was determined for the coating deposited using the air cooled nozzle (FIG. 7). FIG. 9 shows the conductivity as a function of temperature. The conductivity at 250° C. was estimated to be approximately 45% of a dense beta″-alumina substrate fabricated using traditional ceramic processing methods.

The microstructures described in the figures demonstrate the feasibility of depositing a beta″-alumina coating with a localized crack-free microstructure. For example, a crack-free microstructure with a porosity of around 11% was deposited, using the water cooled nozzle. An air cooled nozzle also demonstrated a microstructure without cracks, with a lower porosity (5%).

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed:

1. A method for preparing an electrolyte separator for an electrochemical device, comprising the step of applying a beta″-alumina (beta double prime alumina) coating composition, or a precursor thereof, to a porous substrate, by an atmospheric, thermal spray technique.

2. The method of claim 1, wherein the substrate comprises a metal or a ceramic material.

3. The method of claim 2, wherein the ceramic material is selected from the group consisting of alumina, zirconia, beta″-alumina, nickel oxide, rutile (TiO₂), and combinations thereof.

4. The method of claim 2, wherein the metal is selected from the group consisting of nickel, chromium, molybdenum, stainless steel, and combinations thereof.

5. The method of claim 2, wherein the substrate is characterized by a porosity of about 5% to about 70%.

6. The method of claim 2, wherein the substrate has an average pore size in the range of about 1 micron to about 30 microns.

7. The method of claim 1, wherein the coating composition comprises beta″-alumina, in powder form.

8. The method of claim 1, wherein the precursors of beta″-alumina comprise a material selected from aluminum halide compounds, aluminum halide-hydrate compounds, boehmite, sodium carbonate, lithium hydroxide monohydrate, alpha-alumina, and combinations thereof.

9. The method of claim 1, wherein the thermal spray technique is selected from high-velocity fuel techniques and plasma spray techniques.

10. The method of claim 9, wherein the high-velocity fuel techniques are selected from high velocity oxy-fuel (HVOF), high velocity air fuel (HVAF), and high velocity liquid fuel (HVLF).

11. The method of claim 9, wherein the plasma technique is selected from vacuum plasma deposition (VPS), radio frequency plasma, plasma transfer arc, and air plasma spray (APS).

12. The method of claim 1, wherein the thermal spray technique is carried out at a temperature that is sufficient to melt the coating composition or its precursors, during application to the substrate.

13. The method of claim 1, wherein the thermal spray technique is a suspension spray technique.

14. The method of claim 13, wherein the thermal spray technique is a suspension HVOF spray technique.

15. The method of claim 1, wherein the coating composition, as cured, has a thickness in the range of about 10 microns to about 250 microns.

16. The method of claim 1, wherein the electrochemical device is a sodium-based thermal battery, in planar or tubular form.

17. An electrochemical device, comprising an anode, a cathode, and an electrolyte separator disposed between the anode and the cathode, wherein the separator comprises a thermally-sprayed layer of beta″-alumina (beta double prime alumina) disposed on a porous substrate.

18. The electrochemical device of claim 1, in the form of a battery or an electric converter.

19. An energy storage device, comprising
a) an anode;
b) a cathode;
c) at least one current collector capable of transmitting electrical current from the device to an external site during operation; and
d) a solid, electrolyte separator disposed between the anode and the cathode, and comprising a thermally-sprayed layer of beta″-alumina (beta double prime alumina) disposed on a porous substrate.

20. The energy storage device of claim 19, wherein the thermally-sprayed layer of beta″-alumina also forms a seal that prevents electrode and electrolyte material from unintentionally flowing out of compartments within the storage device.

21. A battery that comprises a plurality of interconnected energy storage devices in accordance with claim 19.
